(19) United States
(12) Patent Application Publication
(10) Pub. No.: US 2025/0196665 A1
(43) Pub. Date: Jun. 19, 2025

(54) INTEGRATED POWER MODULE FOR ELECTRIC VEHICLE

(71) Applicant: Toyota Motor Engineering & Manufacturing North America, Inc., Plano, TX (US)

(72) Inventors: Feng Zhou, Ann Arbor, MI (US); Shahid Aziz Khan, Garden City, MI (US); Mengqi Wang, Troy, MI (US)

(73) Assignees: Toyota Jidosha Kabushiki Kaisha, Toyota-Shi (JP); Toyota Motor Engineering & Manufacturing North America, Inc., Plano, TX (US); THE REGENTS OF THE UNIVERSITY OF MICHIGAN, Ann Arbor, MI (US)

(21) Appl. No.: 18/814,213

(22) Filed: Aug. 23, 2024

Related U.S. Application Data
(60) Provisional application No. 63/612,034, filed on Dec. 19, 2023.

(51) Int. Cl. B60L 50/64; H01F 38/42; H05K 1/18

(52) U.S. Cl. CPC B60L 50/64; H05K 1/185; H01F 38/42

(57) ABSTRACT

An integrated power module is disclosed for use with an electric vehicle. The power module includes: a motor drive printed circuit board having a bare-die semiconductor device embedded therein; and an onboard charger printed circuit board having a planar transformer embedded therein and an electrical connector. The onboard charger printed circuit board is configured to operate in a charging mode to supply a first amount of electricity to a battery of the electric vehicle. The electrical connector is configured to supply the first amount of electricity from an external electricity source and to the planar transformer.

The present application claims priority from U.S. Provisional Application No. 63/612,034 filed Dec. 19, 2023, the entire disclosure of which is incorporated herein by reference.

### BACKGROUND

Embodiments relate to power modules for electric vehicles (EVs).

### SUMMARY

An aspect of the present disclosure is drawn to an integrated power module (IPM) for use with an EV. The power module includes: a motor drive printed circuit board having a bare-die semiconductor device (BDSD) embedded therein; and an onboard charger printed circuit board (PCB) having a planar transformer embedded therein and an electrical connector. The onboard charger PCB may be configured to operate in a charging mode to supply a first amount of electricity to a battery of the EV. The electrical connector may be configured to supply the first amount of electricity from an external electricity source and to the planar transformer.

In some embodiments of this aspect, the IPM further includes a housing configured to house the motor drive PCB and the onboard charger PCB. In some of these embodiments, the housing is further configured to house the battery of the EV.

In some embodiments of this aspect, the motor drive PCB includes: a first PCB layer; a second PCB layer; a third PCB layer; and a fourth PCB layer. The second PCB layer is disposed between the first PCB layer and the third PCB layer. The third PCB layer is additionally disposed between the second PCB layer and the fourth PCB layer. The BDSD is embedded between the second PCB layer and the third PCB layer.

In some embodiments of this aspect, the planar transformer includes a flyback transformer. In some of these embodiments, the flyback transformer includes: a primary winding configured to generate primary winding magnetic flux from the first amount of electricity from the external electricity source; a primary-side auxiliary winding configured to couple with the primary winding to generate primary auxiliary electricity from the primary winding magnetic flux for use by the onboard charger PCB; a secondary-side auxiliary winding configured to couple with the primary winding to generate secondary auxiliary electricity from the primary winding magnetic flux for use by the motor drive PCB; and a secondary-side winding configured to couple with the primary winding to generate a second amount of electricity to be provided to the battery from the primary winding magnetic flux.

In some embodiments of this aspect, the motor drive PCB additionally includes: a copper via connected to the embedded BDSD; and a thermal via to provide a path for heat to flow from the embedded BDSD.

Another aspect of the present disclosure is drawn to an EV including: an electric motor; a battery configured to store electricity and to supply the stored electricity to the electric motor; and an IPM configured to provide a first amount of electricity to the battery.

The IPM includes: a motor drive PCB having a BDSD embedded therein; and an onboard charger PCB having a planar transformer embedded therein and an electrical connector. The onboard charger PCB may be configured to operate in a charging mode to supply the first amount of electricity to the battery. The electrical connector may be configured to supply the first amount of electricity from an external electricity source and to the planar transformer.

In some embodiments of this aspect, the IPM further includes a housing configured to house the motor drive PCB and the onboard charger PCB. In some of these embodiments, the housing is further configured to house the battery of the EV.

In some embodiments of this aspect, the motor drive PCB includes: a first PCB layer; a second PCB layer; a third PCB layer; and a fourth PCB layer. The second PCB layer is disposed between the first PCB layer and the third PCB layer. The third PCB layer is additionally disposed between the second PCB layer and the fourth PCB layer. The BDSD is embedded between the second PCB layer and the third PCB layer.

In some embodiments of this aspect, the planar transformer includes a flyback transformer. In some of these embodiments, the flyback transformer includes: a primary winding configured to generate primary winding magnetic flux from the third amount of electricity from the external electricity source; a primary-side auxiliary winding configured to couple with the primary winding to generate primary auxiliary electricity from the primary winding magnetic flux for use by the onboard charger PCB; a secondary-side auxiliary winding configured to couple with the primary winding to generate secondary auxiliary electricity from the primary winding magnetic flux for use by the motor drive PCB; and a secondary-side winding configured to couple with the primary winding to generate the first amount of electricity to be provided to the EV from the primary winding magnetic flux.

In some embodiments of this aspect, the motor drive PCB additionally includes: a copper via connected to the embedded BDSD; and a thermal via to provide a path for heat to flow from the embedded BDSD.

Another aspect of the present disclosure is drawn to a method of operating an EV having an electric motor, a battery and an IPM. The method includes: providing, in an electricity-supplying state, a first amount of electricity to the electric motor from the battery; and charging, in a charging state and via the IPM, the battery from an external electricity source. The IPM includes: a motor drive PCB having a BDSD embedded therein; and an onboard charger PCB having a planar transformer embedded therein and an electrical connector. The onboard charger PCB may be configured to operate in a charging mode to supply a first amount of electricity to the battery. The electrical connector is configured to supply the first amount of electricity from the external electricity source and to the planar transformer.

In some embodiments of this aspect, the charging, in a charging state and via the IPM, the battery from the external electricity source includes charging via the IPM further includes a housing configured to house the motor drive PCB motor and the onboard charger PCB. In some of these embodiments, the charging, in a charging state and via the IPM, the battery from the external electricity source includes charging via the IPM wherein the housing is further configured to house the battery.

In some embodiments of this aspect, the charging, in a charging state and via the IPM, the battery from the external electricity source includes charging via the IPM wherein the motor drive PCB includes: a first PCB layer; a second PCB layer; a third PCB layer; and a fourth PCB layer. The second PCB layer is disposed between the first PCB layer and the third PCB layer. The third PCB layer is additionally disposed between the second PCB layer and the fourth PCB layer. The BDSD is embedded between the second PCB layer and the third PCB layer.

In some embodiments of this aspect, the charging, in a charging state and via the IPM, the battery from the external electricity source includes charging via the IPM wherein the planar transformer includes a flyback transformer. In some of these embodiments, the charging, in a charging state and via the IPM, the battery from the external electricity source includes charging via the IPM wherein the flyback transformer includes: a primary winding configured to generate primary winding magnetic flux from the first amount of electricity from the external electricity source; a primary-side auxiliary winding configured to couple with the primary winding to generate primary auxiliary electricity from the primary winding magnetic flux for use by the onboard charger PCB; a secondary-side auxiliary winding configured to couple with the primary winding to generate secondary auxiliary electricity from the primary winding magnetic flux for use by the motor drive PCB; and a secondary-side winding configured to couple with the primary winding to generate a second amount of electricity to be provided to the battery from the primary winding magnetic flux.

### BRIEF SUMMARY OF THE DRAWINGS

The accompanying drawings, which are incorporated in and form a part of the specification, illustrate example embodiments and, together with the description, serve to explain the principles of the present disclosure. In the drawings:

FIG. 1A illustrates an EV system that includes an EV and a separate charger;

FIG. 1B illustrates a blown-up view of portions of the EV of FIG. 1A;

FIG. 2 illustrates an enlarged view of the off-board charger for the EV system of FIG. 1A;

FIG. 3 illustrates a transformer within the charger of FIG. 2;

FIG. 4 illustrates an IPM for use with an EV in accordance with aspects of the present disclosure;

FIG. 5 illustrates a side view of an IPM for use with an EV in accordance with aspects of the present disclosure;

FIG. 6 illustrates an example BDSD;

FIG. 7A illustrates a planar view of a top side of a motor drive PCB in accordance with aspects of the present disclosure;

FIG. 7B illustrates a planar view of a bottom side of the motor drive PCB of FIG. 7A;

FIG. 7C illustrates a side view of the motor drive PCB of FIG. 7A;

FIG. 8 illustrates an example layout of a motor drive PCB having a BDSD embedded therein in accordance with aspects of the present disclosure;

FIG. 9A illustrates an example planar transformer of an onboard charger PCB in accordance with aspects of the present disclosure;

FIG. 9B illustrates a side view of the example planar transformer of FIG. 9A;

FIG. 10A illustrates a side view of an example planar transformer in an onboard charger PCB in accordance with aspects of the present disclosure;

FIG. 10B illustrates a planar view of the example planar transformer in the onboard charger PBC of FIG. 10A;

FIG. 11 illustrates a motor control circuit for an EV;

FIG. 12 illustrates a motor control and onboard charging circuit of an integrated power module for use with an EV in accordance with aspects of the present disclosure;

FIG. 13A illustrates an EV system that includes an EV in accordance with aspects of the present disclosure;

FIG. 13B illustrates a blown-up views of portions of the EV of FIG. 13A;

FIG. 14A illustrates a comparative view of a motor control circuit board, and a motor control PCB having an embedded BDSD therein in accordance with aspects of the present disclosure;

FIG. 14B illustrates a bar graph of power density vs a motor control circuit board and a motor drive PCB in accordance with aspects of the present disclosure;

FIG. 14C illustrates a bar graph of a change in power density of a motor control circuit board as compared to that of a motor drive PCB in accordance with aspects of the present disclosure;

FIG. 15A illustrates an off-board charger with the top removed and the back of the PCB of the off-board charger;

FIG. 15B illustrates a planar view of an example onboard charger PCB in accordance with aspects of the present disclosure;

FIG. 15C illustrates a bar graph of power density of the off-board charger of FIG. 15A and an example onboard charger in accordance with aspects of the present disclosure;

FIG. 15D illustrates a bar graph of the percentage increase in power density of an example onboard charger in accordance with aspects of the present disclosure over that of the off-board charger of FIG. 15A;

FIG. 16A illustrates the size of an off-board charger;

FIG. 16B illustrates the size of an example IPM in accordance with aspects of the present disclosure;

FIG. 16C illustrates the size of another example IPM in accordance with aspects of the present disclosure;

FIG. 17A illustrates a bar graph of driving range of an EV and an EV using an IPM in accordance with aspects of the present disclosure; and

FIG. 17B illustrates a bar graph of the percentage change in driving range of an EV as compared to an EV using an example IPM in accordance with aspects of the present disclosure.

### DETAILED DESCRIPTION

Electric Scooters, or E-scooters, have the ability to decarbonize transportation at the cellular level and have become a popular mode of global micromobility, thus becoming a crucial part of the electric transportation revolution. The adaptation of electric scooters in urban centers is crucial, and it is now becoming an integral part of urban mobility planning. The global E-scooter market was valued at USD 19.96 billion in 2020 and is projected to reach USD 40.3 billion by 2030, which is a compound annual growth rate of 8.1%. The North American e-mobility revolution continues, as 58.5 million trips were recorded on the E-Scooters in the year 2022. The overall shared micro-mobility trips are up by 40% since 2018, which is a 35-fold increase from 2010, according to the National Association of City Transportation Officials (NACTO). However, some major challenges need to be solved to increase this continuous growth.

The charging flexibility is one of the major hurdles in this aspect, as the user has to carry a separate off-board charger or return to the starting point for charging purposes, which limits the range, reliability, and flexibility of E-scooters. Electric vehicle (EV) adoption would rise with the usage of onboard chargers, especially for lightweight EVs intended for urban use. Actually, the amount of space available for housing the propulsion battery pack is limited in scooters and three-wheeled vehicles. As a result, traditional battery solutions can only provide autonomy of 20-30 miles.

In actuality, onboard chargers greatly increase the range of EVs and may be used with any domestic outlet and other suitable types of electrical outlets. Therefore, installing a battery charger on a lightweight EV is desirable. It should be mentioned that the power demand for a potential fast charge system is not essential for the power converter design due to the propulsion system's relatively small size. There is currently no mature technique for the onboard charging approach of small mobility vehicles.

A wireless charging approach for e-scooters has been presented. However, due to the required infrastructure, it is not a feasible approach ready for commercialization.

Another approach is based on the integration and utilization of the motor windings and used for charging with the help of some additional components and contactor switches that need to be adjusted to select the required operation mode. However, this approach still needs a lot of space and is a good fit for heavy electric bikes or electric cars which only uses brushless motors and provides sufficient space on the chassis to get connected with the windings.

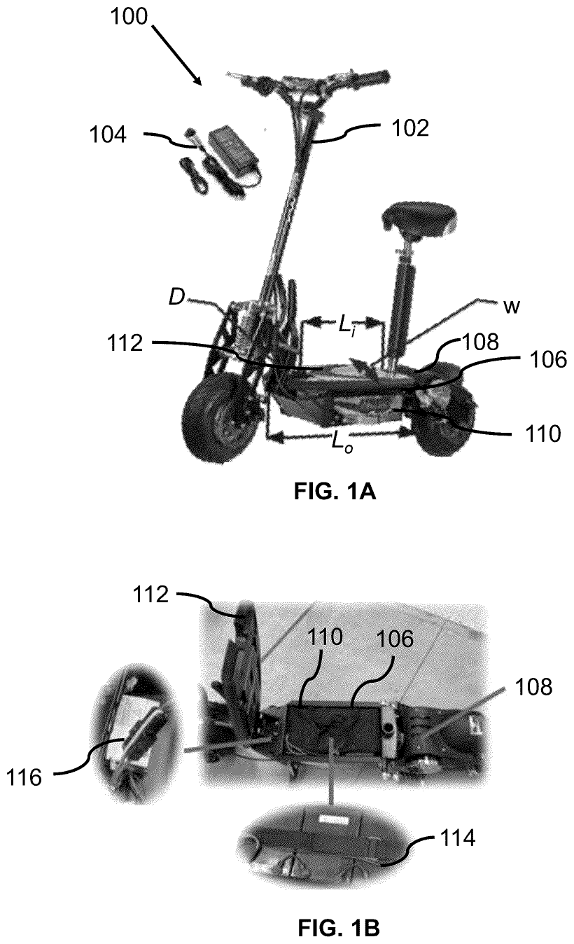

An EV system will now be described in greater detail with reference to FIGS. 1A-3.

FIG. 1A illustrates an EV system 100 that includes an EV 102, in this example an E-scooter, and a separate off-board charger 104.

EV 102 includes a standing platform 106 and an electric motor 108. Standing platform includes a body compartment 110 and a lid 112. Body compartment 110 has an overall lengthLₒ, and an inner lengthLᵢ, a depthD, and a widthW.

FIG. 1B illustrates a blown up view of portions of EV 102. As shown in the figure, lid 112 is open showing the inside of body compartment 110. Within body compartment 110, resides batteries 114 and a motor drive 116. The volume of the space within body compartment 110 is the product of inner lengthLᵢ, depthD, and widthW.

In operation, the user may rest their feet on closed lid 112. Batteries 114 provide electricity to motor drive 116, which drives motor 108 to propel EV 102.

When the batteries 114 are drained, electricity is no longer provided to motor drive 116, which means that EV 102 can no longer be propelled by motor 108. Accordingly, the user must attach off-board charger 104 to batteries 114 so as to recharge them. As mentioned above, this either limits the drive range of EV 102 or inconveniences the user. In particular, if off-board charger 104 is left at the home of the user, then the drive range is limited to a round-trip range, so the user may end up back at home to use off-board charger 104. Alternatively, the user may carry off-board charger 104 on his person, so as to recharge after a one-way longer ranger, which is an inconvenience.

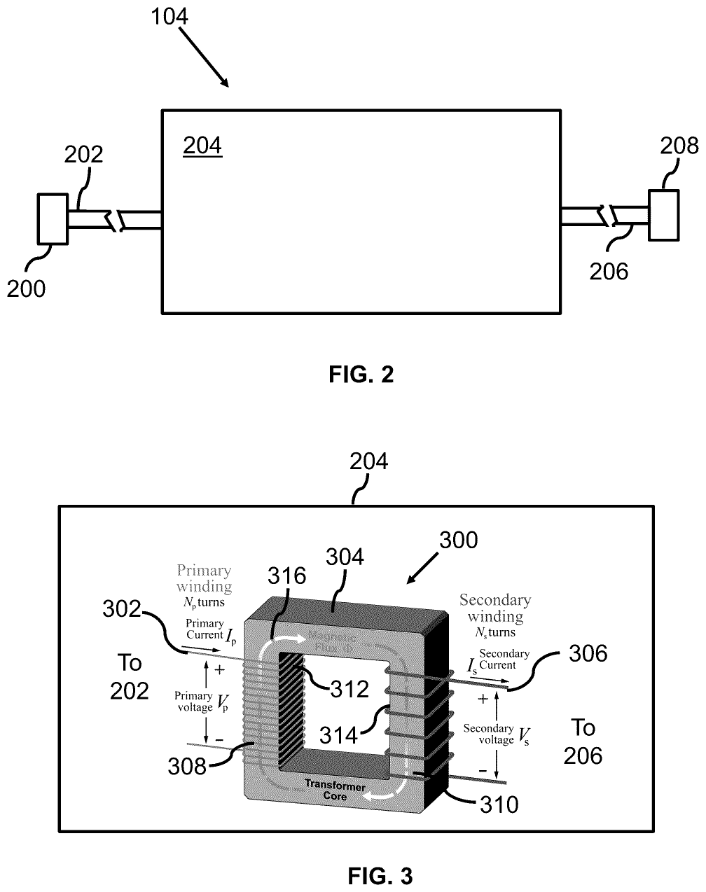

There is no space in body compartment 110 to store off-board charger 104. In particular, all the space within body compartment 110 is taken up by batteries 114 and motor drive 116. By filling as much of body compartment as possible with batteries 114 maximizes the driving range of EV 102. Further, because off-board charger 104 is particularly large, the space it would fill within body compartment 110 would drastically reduce the number of batteries, which would drastically reduce the driving range of EV 102. The large size of off-board charger 104 will be further described with reference to FIGS. 2-3.

FIG. 2 illustrates an enlarged view off-board charger 104. As shown in the figure, off-board charger 104 includes an input plug 200, an input electrical cord 202, a body 204, an output electrical cord 206, and an output plug 208.

Input electrical cord 202 has one end connected to input plug 200 and the other end connected to body 204. Output electrical cord 206 has one end connected to body 204 and the other end connected to output plug 208.

Input plug 200 is configured to be plugged into a standard electrical outlet to receive an AC voltage, whereas output plug 208 is configured to be plugged into an input on EV 102 (not shown). In operation, AC electricity provided by the electrical outlet conducts through input plug 200, through input electrical cord 202 and into body 204. Body 204 converts the AC electricity from input electrical cord 202 to direct current (DC) electricity and outputs the DC electricity to output electrical cord 206, which is conducted to output plug 208, and which is then output to the batteries of EV 102.

A reason that body 204 is particularly large, is that it includes a transformer therein. Some transformer designs are characterized by wound cores that have toroidal or cylindrical geometries, whereas planar transformers have a flat, stacked construction. This will be described in greater detail with reference to FIG. 3

FIG. 3 illustrates a transformer 300 within the off-board charger 104. As shown in FIG. 3, transformer 300 includes an input line 302, a core 304, and an output line 306. Core 304 includes a primary leg 308 and a secondary leg 310. Input line 302 wraps around primary leg 308 to create Nₚ primary winding turns 312, whereas output line 306 wraps around secondary leg 310Nₛ secondary winding turns 314. Transformer 300 works by utilizing the principles of electromagnetic induction and mutual inductance between primary winding turns 312 and secondary winding turns 314.

In particular, primary winding turns 312 receive a primary current, Iₚ, from input electrical cord 202. As I_{P} flows through primary winding turns 312, it creates a changing magnetic field 316 in core 304. This changing magnetic field induces an alternating secondary current, Iₛ, secondary winding turns 314 through electromagnetic induction.

The strength of the corresponding induced voltage in secondary winding turns 314 depends on the ratio of the number of N_{P} to N_{S}. If secondary winding turns 314 has more turns than primary winding turns 312, transformer 300 acts as a step-up transformer, increasing the voltage. Conversely, if secondary winding turns 314 has fewer turns than primary winding turns 312, transformer 300 acts as a step-down transformer, decreasing the voltage. When a transformer is used in a charger, it is typically a step-down transformer.

The currents in primary winding turns 312 and secondary winding turns 314 are inversely proportional to the ratio of their respective turns. If the secondary voltage is higher, I_{S} will be lower, and vice versa, to maintain the same power level (ignoring losses).

What is needed is an EV that includes an onboard charger but does not reduce the amount of space for battery storage.

An integrated power module (IPM) for use with an EV in accordance with aspects of the present disclosure includes an onboard charger without reducing the amount of space for battery storage over that of some EVs.

An IPM for use with an EV in accordance with aspects of the present disclosure leverages the proven flyback topology that is readily used in the e-scooter off-board chargers by designing an application-specific multi-winding planar transformer for the flyback converter with interleaved PCB windings and discontinuous conduction mode (DCM) operation to achieve enhance power density and efficiency. An IPM for use with an e-scooter in accordance with aspects of the present disclosure reduces the overall converter size and can easily fit and work as an onboard charger on the space available on the chassis of the e-scooter.

A flyback converter is a type of switched-mode power supply (SMPS) that provides electrical isolation and voltage conversion between the input and output. It is derived from the buck-boost converter topology by replacing the inductor with a transformer. A flyback converter operates in two modes: when the switch is on (charging the primary), and when the switch is off (discharging energy to the secondary).

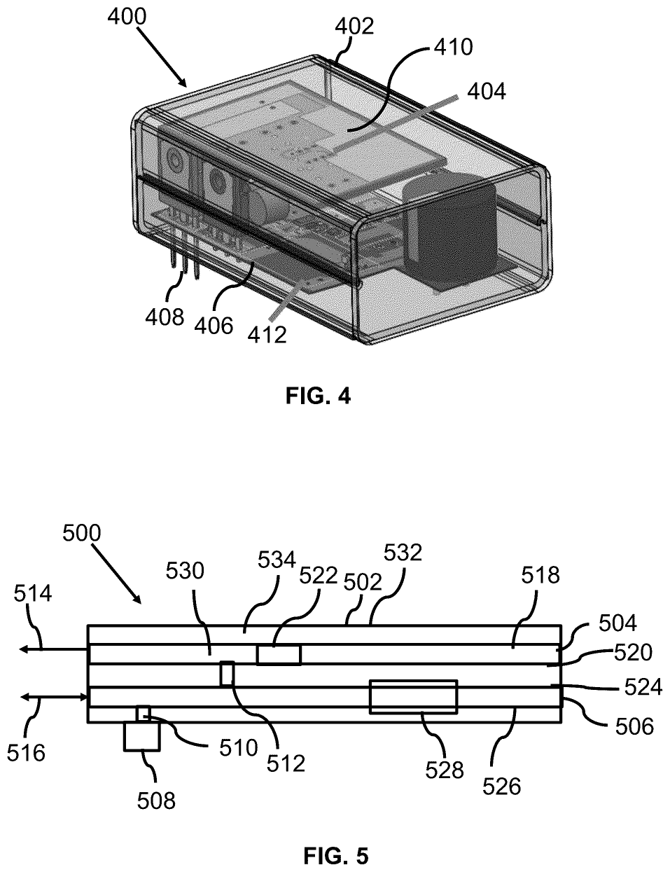

An example IPM for use with an EV in accordance with aspects of the present disclosure will now be described in greater detail with reference to FIGS. 4-17B.

FIG. 4 illustrates an IPM 400 for use with an EV in accordance with aspects of the present disclosure.

As shown in the figure, IPM 400 includes a housing 402, a motor drive PCB 404, an onboard charger PCB 406, and a set of electrical prongs 408. Motor drive PCB 404 includes a BDSD 410 embedded therein. Onboard charger PCB 406 includes a planar transformer embedded therein.

Housing 402 is configured to house motor drive PCB 404 and onboard charger PCB 406, wherein set of electrical prongs 408 extend from onboard charger PCB through and out from housing 402.

A set of electrical prongs 408 are configured to connect to a charging electrical cord (not shown), to receive AC electricity and provide the AC electricity to onboard charger PCB 406.

Motor drive PCB 404 is configured to control the motor (not shown) of the EV. Onboard charger PCB 406 is configured to receive the AC electricity from set of electrical prongs 408 and to transform the AC electricity to DC electricity to charge the batteries (not shown) of the EV. Motor drive PCB 404 includes a BDSD 410 embedded therein. Onboard charger PCB 406 includes a planar transformer 412 embedded therein.

Because motor drive PCB 404 includes a BDSD 410 embedded therein, motor drive PCB 404 occupies less volume than motor drive 116 discussed above with reference to FIG. 1B. Further, because onboard charger PCB 406 has a planar transformer embedded therein, onboard charger PCB 406 occupies less volume than off-board charger 104 discussed above with reference to FIGS. 2-3. In fact, the combined volume of motor drive PCB 404 and onboard charger PCB 406 and housing 402 occupy less volume than motor drive 116. For this reason, in accordance with aspects of the present disclosure, IPM 400 pay replace motor drive 116 and an off-board charger, without having to sacrifice volume in an EV that is dedicated to battery storage.

The overall operation of an IPM in accordance with aspects of the present disclosure will now be described in greater detail with reference to FIG. 5.

FIG. 5 illustrates a schematic side view of an IPM 500 for use with an EV in accordance with aspects of the present disclosure.

As shown in the figure, IPM 500 includes a housing 502, a motor drive PCB 504, an onboard charger PCB 506, an electricity receiving plug 508, a conducting line 510, a conducting line 512, a motor drive output line 514, and a battery line 516. Motor drive PCB 504 has a top side 518 and a bottom side 520 and includes a BDSD 522 embedded therein. Onboard charger PCB 506 has a top side 524 and a bottom side 526, includes a planar transformer 528 embedded therein. IPM 500 corresponds to IPM 400, but does not include specifics of circuitry on motor drive PCB 504 or onboard charger PCB 506.

Housing 502 is configured to house motor drive PCB 504, onboard charger PCB 506, conducting line 510, and conducting line 512.

In this example embodiment, top side 524 of onboard charger PCB 506 is separated from bottom side 520 of motor drive PCB 504 by a space 530. Space 530 provides a volume for additional circuitry (not shown) on onboard charger PCB 506. Top side 518 of motor drive PCB 504 is separated from an inner surface 532 of housing 502 by a space 534. Space 534 provides a volume for additional circuitry (not shown) on motor drive PCB 504.

Electricity receiving plug 508 is incorporated into housing 502 and is in electrical connection with conducting line 510. Conducting line 510 is additionally in electrical connection with a conducting trace (not shown) on bottom side 526 of onboard charger PCB 506. A conducting trace (not shown) on top side 524 of onboard charger PCB 506 is in electrical connection with battery line 516. A conducting trace (not shown) on top side 524 of onboard charger PCB 506 is in electrical connection with conducting line 512. Conducting line 512 is additionally in electrical connection with a conducting trace (not shown) on bottom side 520 of motor drive PCB 504. A conducting trace (not shown) on top side 518 of motor drive PCB 504 is additionally in electrical connection with motor drive output line 514.

Consider the operation of an EV having IPM 500. During a driving mode, electricity is supplied to onboard charger PCB 506 from a battery (or batteries) (not shown) in the EV via battery line 516. The electricity is conducted through the conducting trace on top side 524 of onboard charger PCB 506 to conducting line 512 and then to the conducting trace (not shown) on bottom side 520 of motor drive PCB 504. The conducting trace on bottom side 520 of motor drive PCB 504 conducts the electricity to BDSD 522 embedded therein. BDSD 522 and additional circuitry (not shown) on motor drive PCB 504 output a drive signal the conducting trace on top side 518 of motor drive PCB 504, which is then output to the motor of the EV via motor drive output line 514.

Motor drive PCB 506 acts as the brain of the EV, regulating the power flow from the battery(ies) to the motor(s) and controlling various functions, including throttle input, motor control, safety features, and monitoring/feedback.

With respect to throttle input, motor drive PCB 506 receives an input signal from the throttle, which is typically a twist grip or thumb lever. This input signal indicates the desired speed or acceleration from the rider. With respect to power regulation, based on the throttle input, motor drive PCB 506 regulates the amount of electrical power supplied to the motor(s). It does this by controlling the flow of current from the battery using embedded BDSD 522. With respect to motor control, motor drive PCB 506 precisely times and modulates the electrical signals sent to the motor's windings, ensuring smooth and efficient operation. With respect to safety features, motor drive PCB 506 incorporates various safety features to protect the EV and rider. These may include overcurrent protection, overvoltage protection, thermal monitoring, and automatic power cutoff in case of faults or excessive temperatures. With respect to monitoring/feedback, motor drive PCB 506 receives feedback from various sensors, such as hall effect sensors or encoders, to monitor the motor's speed and position. This information is used to adjust the power output and ensure smooth operation.

During a charging mode, electricity is supplied to electricity receiving plug 508 via an external electrical cord (not shown). The electricity is conducted through conducting line 510 to a conducting trace (not shown) on bottom side 526 of onboard charger PCB 506. The electricity is then supplied to planar transformer 528, which steps down the electricity and is then provided to the additional circuitry (not shown) on top side 524 of onboard charger PCB 506. The additional circuitry converts the stepped-down electricity to direct current electricity, which is then supplied to the battery of the EV via battery line 516.

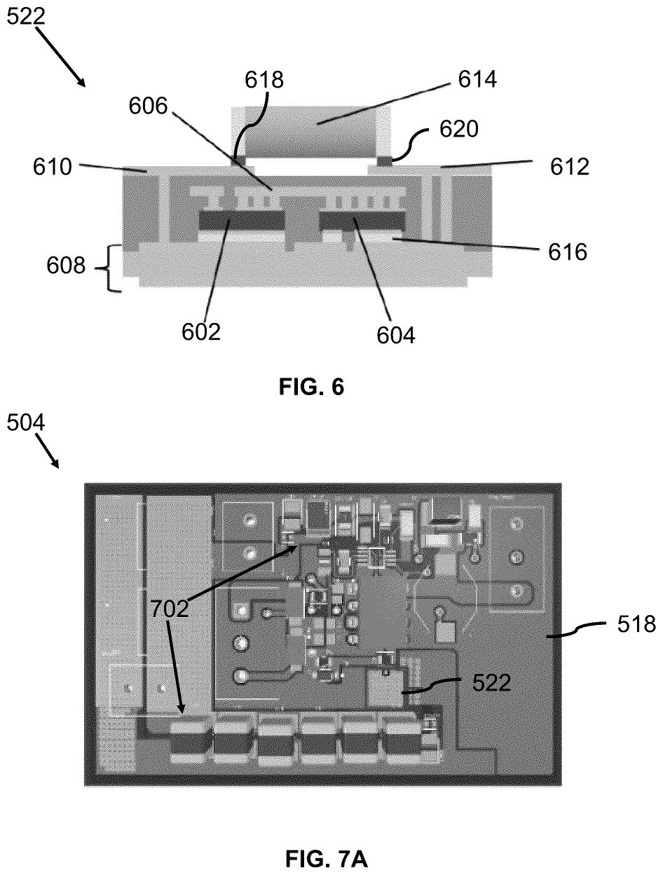

The combination of the use of an embedded BDSD in a motor drive PCB and an embedded planar transformer in an onboard charger PCB in accordance with aspects of the present disclosure, a IPM has a very compact size. A motor drive PCB having an embedded BDSD will now be further described with reference to FIG. 6-8.

A BDSD is a semiconductor device used for power electronics applications, where the semiconductor die (the small block of semiconducting material containing the functional circuit) is not packaged or encapsulated. Power semiconductor devices are designed to operate as switches or rectifiers in power conversion and control systems. They are optimized for switching operation rather than linear operation. Common examples include power diodes, thyristors (like silicon-controlled rectifiers or SCRs), insulated-gate bipolar transistors (IGBTs), and power metal oxide semiconducting field effect transistors (MOSFETs). In a bare die configuration, the semiconductor die itself is exposed without any packaging material around it. This allows for better thermal dissipation compared to packaged devices, as the heat can be directly extracted from the bare die. Bare dies are often attached directly to a substrate, leadframe, or heatsink using conductive die attach materials like silver epoxy or solder.

FIG. 6 illustrates an example of BDSD 522. As shown in the figure, BDSD 522 includes a high side (HS) MOSFET die 602, a low side (LS) MOSFET die 604, a plurality of microvias 606, a direct copper bonding (DCB) substrate 608, a positive direct current (DC) contact 610, a negative DC contact 612, a DC link capacitor 614, and a silver (Ag) sinter 616, DC link capacitor 614 includes a positive contact 618 in electrical connection with positive DC contact 606 and a negative contact 620 in electrical connection with negative DC contact 612.

HS MOSFET die 602 is attached face up on DBC substrate 608 via Ag sinter 616. LS MOSFET die 604 is attached face down (flipped) on the DBC substrate, also via Ag sinter 616. DBC substrate 608 provides electrical isolation between HS MOSFET die 602 and LS MOSFET die 604, as well as a thermal path for heat dissipation. The plurality of microvias 606 formed in the PCB layers above and below DBC substrate 608 make electrical connections to the source, gate, and drain terminals of HS MOSFET die 602 and LS MOSFET die 604.

DC link capacitor 614 is embedded within the PCB layers to minimize the stray inductance of the commutation loop formed by HS MOSFET die 602 and LS MOSFET die 604. In particular, DC link capacitor 614 acts as a temporary energy storage element to support the flow of current during the switching transitions of HS MOSFET die 602 and LS MOSFET die 604. Further, DC link capacitor 614 filters out high-frequency ripple currents generated by the switching operation, providing a smooth DC link voltage. Still further, DC link capacitor 614 helps snub voltage overshoots and ringing during fast switching transitions, protecting HS MOSFET die 602 and LS MOSFET die 604 from overvoltage spikes. BDSD 522 integrates HS MOSFET die 602 and LS MOSFET die 604 and DC link capacitor 614 in a low-inductance planar structure, enabling fast switching with reduced overshoots and ringing.

A BDSD may be embedded in a motor drive PCB in accordance with aspects of the present disclosure by any known method, non-limiting examples of which are disclosed in: Tull Huesgen, Printed circuit board embedded power semiconductors: A technology review, Electronics Integration Laboratory, University of Applied Sciences Kempten, Bahnhofstr. 61, 87435 Kempten, Germany; Feix et al, Embedded Very Fast Switching Module for SiC PowerMOSFETs, Proceedings of PCIM Europe 2015, International Exhibition and Conference for Power Electronics, Intelligent Motion, Renewable Energy and Energy Management 19-20 May 2015; Regnat et al, Optimized power modules for silicon carbide mosfet, IEEE Transactions on Industry Applications, 54, 1634-1644 (2018); Sharma et al., Fabrication of PCB Embedded 1200V/50 A Power Module and Benchmarking with Commercial DBC-based Package, CIPS 2018, 10th International Conference on Integrated Power Electronics Systems, Stuttgart, Germany, 2018, pp. 1-6; Pascal et al. (2018), Experimental investigation of the reliability of Printed Circuit Board (PCB)-embedded power dies with pressed contact made of metal foam, Microelectronics Reliability, 88, 707-714; and Polezhaev et al., Development of a novel 600V/50 A power package with semiconductor chips sandwiched between PCB substrates using double-side Ag-sintering, PCIM Europe 2019, International Exhibition and Conference for Power Electronics, Intelligent Motion, Renewable Energy and Energy Management, Nuremberg, Germany, 2019, pp. 1-6, the entire disclosures of which are incorporated herein by reference.

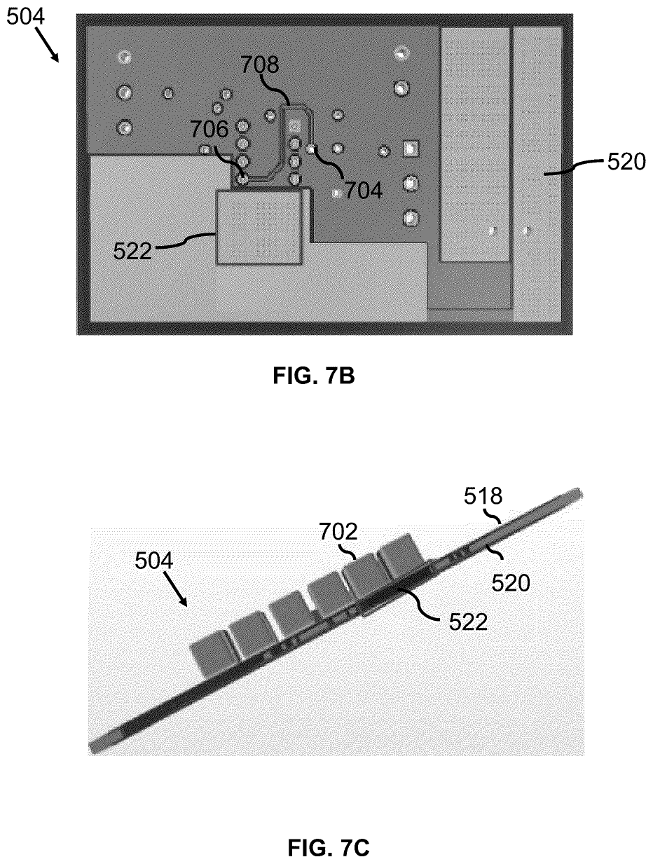

FIG. 7A illustrates a planar view of top side 518 of motor drive PCB 504 in accordance with aspects of the present disclosure. As shown in the figure, motor drive PCB 504 includes embedded BDSD 522 and additional circuit devices 702 on top side 518.

FIG. 7B illustrates a planar view of a bottom side 520 of motor drive PCB 504. As shown in the figure, bottom side 520 includes an input via 704 and a conducting via 706. A conducting trace 708 on a top of a bottom layer of motor drive PCB 504 can be viewed through bottom side 520. The location of embedded BDSD 522 is also outlined in the figure. Input via 704 is configured to electrically connect with conducting line 512 as shown in FIG. 5. As such, returning to FIG. 7B, DC electricity is supplied by the battery(ies) to input via 704, through the bottom layer of motor drive PCB 504 by way of input via 704 to conducting trace 708, and to conducting via 706. As will be explained in more detail below, motor drive PCB 504 includes a plurality of PCB layer.

FIG. 7C illustrates a side view of motor drive PCB 504.

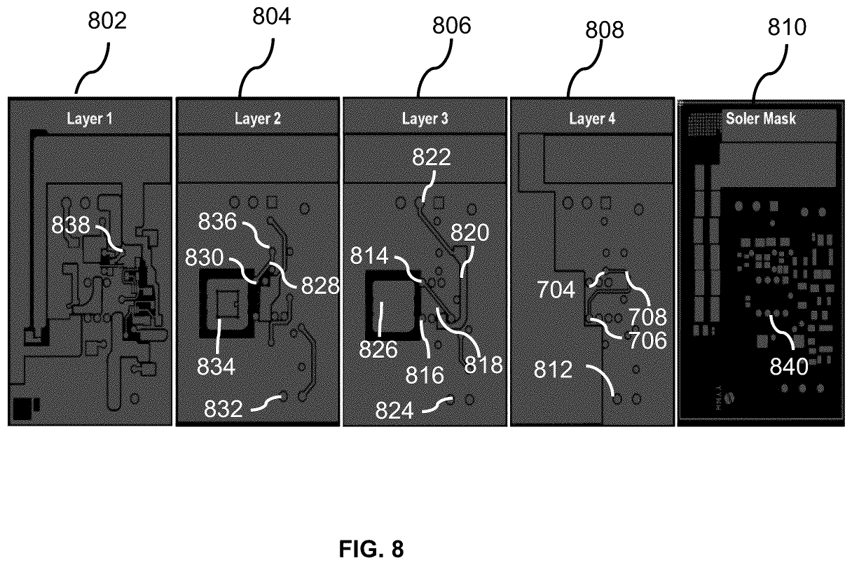

In operation, DC electricity is supplied to the bottom of embedded BDSD 522, which is then passed through to additional circuit devices 702 on top side 518. This will be described in greater detail with reference to FIG. 8.

FIG. 8 illustrates an example layout of motor drive PCB 504 having BDSD 522 embedded therein in accordance with aspects of the present disclosure.

As shown in the figure, motor drive PCB 504 includes a layer 802, a layer 804, a layer 806, a layer 808, and a layer 810.

Layer 808 is the bottom layer of motor drive PCB 504. A front side of layer 808 as shown in the figure includes conducting via 704, conducting trace 708, conducting via 706, and a plurality of vias, a sample of which is indicated as via 812. The back side (not shown) of layer 808 corresponds to bottom side 520 of motor drive PCB 504 as illustrated in FIG. 7B.

A conducting trace, as used herein, may be a deposited thin film of any known electrical conductor, a non-limiting example of which includes copper. A via, as used herein with motor drive PCB 504 and onboard charger PCB 506, is a small hole through a PCB layer.

Layer 808 is the bottom layer of motor drive PCB 504. A front side of layer 808 as shown in the figure includes conducting via 704, conducting via 706, conducting trace 708, and a plurality of vias, a sample of which is indicated as via 812. The back side (not shown) of layer 808 corresponds to bottom side 520 of motor drive PCB 504. As the plurality of vias, such as via 812, are not filled with a conductor, i.e., they are each merely a through hole, the plurality of vias enable air to pass through layer 808 in order to reduce heat.

During assembly, layer 806 will be stacked on layer 808, wherein a back side of layer 806 will be disposed on the front side of layer 808. A front side of layer 806 as shown in the figure includes a conducting via 814, a conducting via 816, a conducting trace 818, a conducting trace 820, a conducting via 822, and a plurality of vias, a sample of which is indicated as via 824. An area 826 may be machined out to a predetermined depth to receive BDSD 522. Conducting via 816 is configured to electrically connect to an input terminal of BDSD 522 when mounted in area 826. Conducting via 814 is configured to electrically connect to a gate control terminal of BDSD 522 when mounted in area 826. As the plurality of vias, such as via 824, are not filled with a conductor, i.e., they are each merely a through hole, the plurality of vias enable air to pass through layer 806 in order to reduce heat.

During assembly, layer 804 will be stacked on layer 806, wherein a back side of layer 804 will be disposed on the front side of layer 806. A front side of layer 804 as shown in the figure includes a conducting trace 828, a conducting via 830, and a plurality of vias, a sample of which is indicated as via 832. An area 834 may be machined out from the back side to a predetermined depth to cover BDSD 522. Conducting via 830 is configured to contact an output terminal of BDSD 522 when mounted in area 824. Conducting trace 830 is configured to conduct the output of BDSD 522 to a contact point 836. As the plurality of vias, such as via 832, are not filled with a conductor, i.e., they are each merely a through hole, the plurality of vias enable air to pass through layer 804 in order to reduce heat.

During assembly, layer 802 will be stacked on layer 804, wherein a back side of layer 802 will be disposed on the front side of layer 804. A front side of layer 802 includes a conducting via 838 that is configured to electrically connect to a contact point 836.

During assembly, solder layer 810 will be stacked on layer 802, wherein a back side of solder layer 810 will be disposed on the front side of layer 802. Solder layer 810 includes a plurality of copper solder landings, a sample of which is indicated as copper solder landing 840. The plurality of copper solder landings enable additional circuit devices 702 to be soldered onto solder layer 810.

In operation, conducting via 704 receives DC electricity from the battery(ies) (not shown) by way of battery line 516 and conducting line 512 in layer 808. The DC electricity is conducted through conducting trace 708 to conducting via 706 and up through layer 808.

The DC electricity is then conducted to the input terminal of BDSD 522 by way of conducting via 816 in layer 806. In some embodiments, a dedicated integrated circuit (not shown) may be implemented to generate a gate control signal for BDSD 522.

The output terminal of BDSD 522 outputs an AC signal at conducting via 830 in layer 804. The output AC signal is conducted through conducting trace 828 to conducting via 836. The output AC signal is then conducted through conducting via 838 of layer 802 to solder layer 810, wherein the output AC signal is then provided to additional circuit devices 702.

By embedding BDSD 522 within the plurality of layers of motor drive PCB 504, the overall volume of motor drive PCB 504 is drastically reduced over that of motor drive 116, as discussed above with reference to FIG. 1B. Further volume is saved by implementing an embedded planar transformer in an onboard charger PCB.

A planar transformer design provides increased power density and efficiency over that of some transformers. Higher power density and more compact integration into power electronic systems are made possible by the planar geometry's more effective cooling and heat dissipation capabilities. Because of their interleaved winding construction, planar transformers also have lower leakage inductance and better magnetic coupling between windings, which reduces switching losses and enhances transient response. Additionally, the planar design provides more control over parasitic components like leakage inductance and stray capacitance, enabling more precise transformer modeling and control. Moreover, planar transformers are more suited for automated manufacturing processes by nature, which results in reduced production costs and increased dependability.

A flyback transformer may operate in either a continuous conduction mode (CCM) or a dis-continuous conduction mode (DCM), each with associated advantages and disadvantages.

In a CCM, the secondary current never reaches zero before the start of the next switching cycle. This means that the transformer is continuously transferring energy to the output during each switching cycle. In a DCM the transformer's core completely demagnetizes or discharges all of its stored energy to the secondary winding before the start of the next switching cycle.

For a goal of increased power density, DCM offers suitable switching conditions as the diodes operate at zero current before becoming reverse biased. Further, since the average energy storage is small compared to CCM, the size of flyback transformer can be reduced by operating in DCM mode.

For purposes of discussion, consider an e-scooter requiring 1 KW and being fixed with 36V battery system. In an example embodiment, a multi-winding planar transformer to be embedded in an onboard charger PCB of an IPM for use with such an e-scooter in accordance with aspects of the present disclosure may: receive an input voltage of 90 V to 240 V (AC); provide a secondary output voltage of 36 V (DC); provide an auxiliary output voltage of 18 V (DC); have a primary inductance of 313 μH; have a leakage inductance of 1.6 μH; and have a primary inductance of 65 KHz.

However it should be understood that a multi-winding planar transformer to be embedded in an onboard charger PCB of an IPM in accordance with aspects of the present disclosure may also be used with E-scooters having other electrical systems of other sizes and capacities, as well as with other rechargeable devices other than E-scooters.

The power handling capacity of a transformer is determined by the window are a product WaAc, where Wₐ is the available core window area and A_{c} is the effective core cross-sectional area. For this scenario, the window area product comes out to be 2.2157 cm⁴. However, no available off-the-shelf planar cores can meet the required core area and power handling capability of 75 W, which implies that a customized core design was needed. In a non-limiting example embodiment, a MnZn Ferrite material was selected for the core, which offers low core loss and high saturation flux density, making it a good candidate for planar designs. The calculation for the required number of turns is accomplished once the core material is chosen.

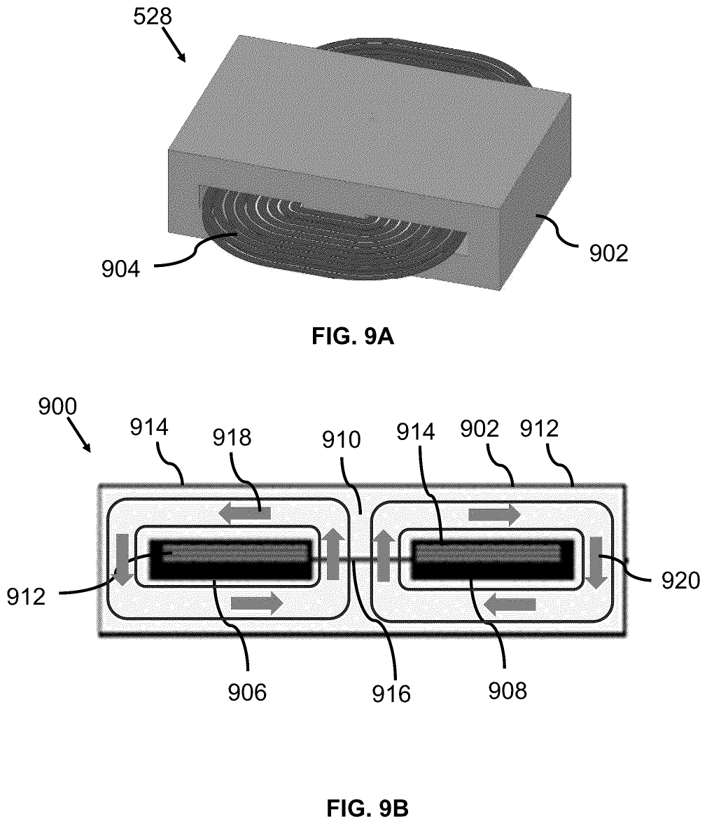

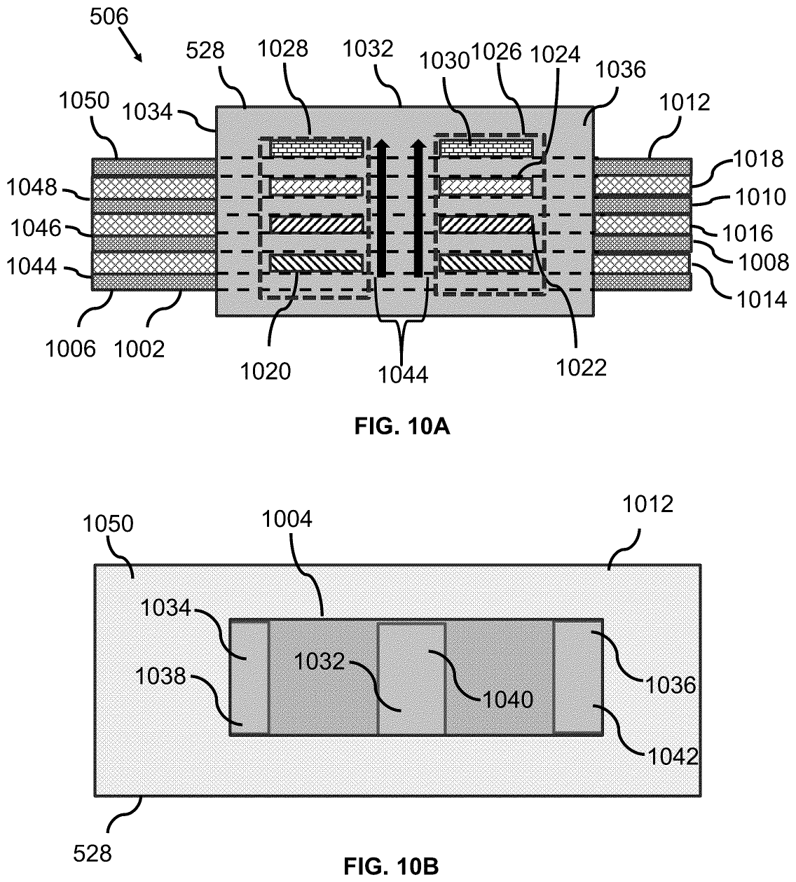

An example structure and windings layer stack of a planar transformer in accordance with aspects of the present disclosure will now be described in greater detail with reference to FIGS. 9A-10.

FIG. 9A illustrates planar transformer 528 of onboard charger PCB 506 in accordance with aspects of the present disclosure.

As shown in the figure, planar transformer 528 includes a core 902 and a plurality of FIG. 9B illustrates a cross-sectional side view of example planar transformer 528.

As shown in FIG. 9B, core 902 is shaped so as to have a space 906 and a space 908, which are separated from one another by a central portion 910. Plurality of windings 904 wind around central portion 910 from space 906 to space 908, wherein the portion of plurality of windings 904 within space 906 are indicated as windings 912 and the portion of plurality of windings 904 within space 908 are indicated as windings 914. It should be further noted that central portion 910 includes an air gap 916.

When current flows through plurality of winding 904, magnetic flux flows through core 902 in a counter clockwise direction around space 906 as indicated by arrows around space 906, a sample of which is indicated as arrow 918, and magnetic flux flows through core 902 in a clockwise direction around space 908 as indicated by arrows around space 908, a sample of which is indicated as arrow 920. As a flyback transformer, air gap 916 allows core 902 to store energy temporarily. This is analogous to a reservoir that stores water, allowing planar transformer 528 to release energy when needed.

FIG. 10A illustrates a cross-sectional side view of example planar transformer 528 in onboard charger PCB 506 in accordance with aspects of the present disclosure.

As shown in the figure, planar transformer 528 includes a multi-layered PCB 1002 and a core 1004. Multi-layered PCB 1002 includes a PCB 1006, a PCB 1008, a PCB 1010, a PCB 1012, an insulation layer 1014, an insulation layer 1016, and insulation layer 1018, a primary winding 1020, a primary auxiliary winding 1022, a secondary auxiliary winding 1024, and a secondary winding 1026.

Core 1004 includes an open space 1028 and an open space 1030, separated by a central portion 1032. Open space 1028 is bounded by an outer leg portion 1034 of core 1004, whereas open space 1030 is bounded by an outer leg portion 1036 of core 1004. Each of primary winding 1020, primary auxiliary winding 1022, secondary auxiliary winding 1024, and secondary winding 1026 wraps around central portion 1032 in open space 1028 and open space 1030.

FIG. 10B illustrates a planar view of planar transformer 528 in onboard charger PCB 506 in accordance with aspects of the present disclosure.

As shown in the figure, pre-cut holes pass through multi-layered PCB 1002 to receive core 1004. For example, a hole 1038 is formed for outer leg portion 1034 of core 1004, a hole 1040 is formed for central portion 1032 of core 1004, and a hole 1042 is formed for outer leg portion 1036 of core 1004.

Returning to FIG. 10A, primary winding 1020 is deposited on a top surface 1044 of PCB 1006 so as to wind around central portion 1032. Primary auxiliary winding 1022 is deposited on a top surface 1046 of PCB 1008 so as to wind around central portion 1032. Secondary auxiliary winding 1024 is deposited on a top surface 1048 of PCB 10 to wind around central portion 1032. Secondary winding 1026 is deposited on a top surface 1050 of PCB 1012 so as to wind around central portion 1032.

Insulation layer 1014 provides structural support and reduces heat transfer between PCB 1006 and PCB 1008. Insulation layer 1016 provides structural support and reduces heat transfer between PCB 1008 and PCB 1010. Insulation layer 1018 provides structural support and reduces heat transfer between PCB 1010 and PCB 1012.

In operation, referring to FIG. 5, AC current (from an external supply, not shown) is input from electricity receiving plug 508, through conducting line 510 to conduction lines (not shown) on onboard charger PCB 506 and ultimately to planar transformer 528.

Returning to FIG. 10A, the AC current is fed to primary winding 1020, which generates a magnetic flux in core 1004. As shown by the double arrows 1044 in central portion 1032 of core, this magnetic flux passes through each of primary auxiliary winding 1022, secondary auxiliary winding 1024, and secondary winding 1026.

Based on the ratio of windings between primary winding 1020 and primary auxiliary winding 1022, an output voltage at primary auxiliary winding 1022 may be either stepped-up or stepped-down, as discussed above. The voltage in primary auxiliary winding 1022 may be used by predetermined circuitry on onboard charger PCB. In some embodiments, the step-down auxiliary voltage may be used to power the other loads such as different sensing integrated circuits and pulse generating integrated circuits for the gates of the MOSFETs within BDSD 522. Moreover, sensors and integrated circuits for protection (over voltage/over current) are all operated by the auxiliary output voltage.

Based on the ratio of windings between primary winding 1020 and secondary auxiliary winding 1024, an output voltage at secondary auxiliary winding 1022 may be configured as a stepped-down voltage, as discussed above. The voltage in secondary auxiliary winding 1022 may be used by other predetermined circuitry on onboard charger PCB, which may need a different voltage to operate as compared to those supplied by the voltage from primary auxiliary winding 1022. In some embodiments, the step down auxiliary voltage is used to power the other loads such as different sensing integrated circuits and pulse generating integrated circuits for the gates of MOSFETs used therein. Moreover, sensors and integrated circuits for protection (over voltage/over current) are all operated by through the auxiliary output voltage.

Based on the ratio of windings between primary winding 1020 and secondary winding 1026, an output voltage at secondary winding 1022 may be either stepped-up or stepped-down, as discussed above. The voltage in secondary winding 1022 may be used charge batteries of the EV. For example, returning to FIG. 5, the voltage in secondary winding may be processed by additional circuitry (not shown) to ultimately output a DC voltage to the batteries via battery line 516.

Under operational conditions, a transformer's core and copper losses will cause a temperature increase. To prevent harm to the transformer or the remaining circuitry, this rise must remain below a maximum permitted value. Division of the windings on the PCB layers is an important step with thermal and magnetic consequences. In accordance with aspects of the present disclosure, instead of using the traditional approach to design the required PCB layers, an interleaved approach is adopted, which sandwiched the other layers into the primary layers as shown in the layer stack in FIG. 10A, that reduces the proximity effect.

The analysis of both related winding structure and an interleaved winding structure in accordance with aspects of the present disclosure was performed. The analysis showed that the current density distribution is much better in the interleaved arrangement, which also translates to better efficiency depicted from the ohmic loss analysis. The magnetostatic analysis performed after the selection of the interleaved winding arrangement confirms the required performance of the designed planar inductor.

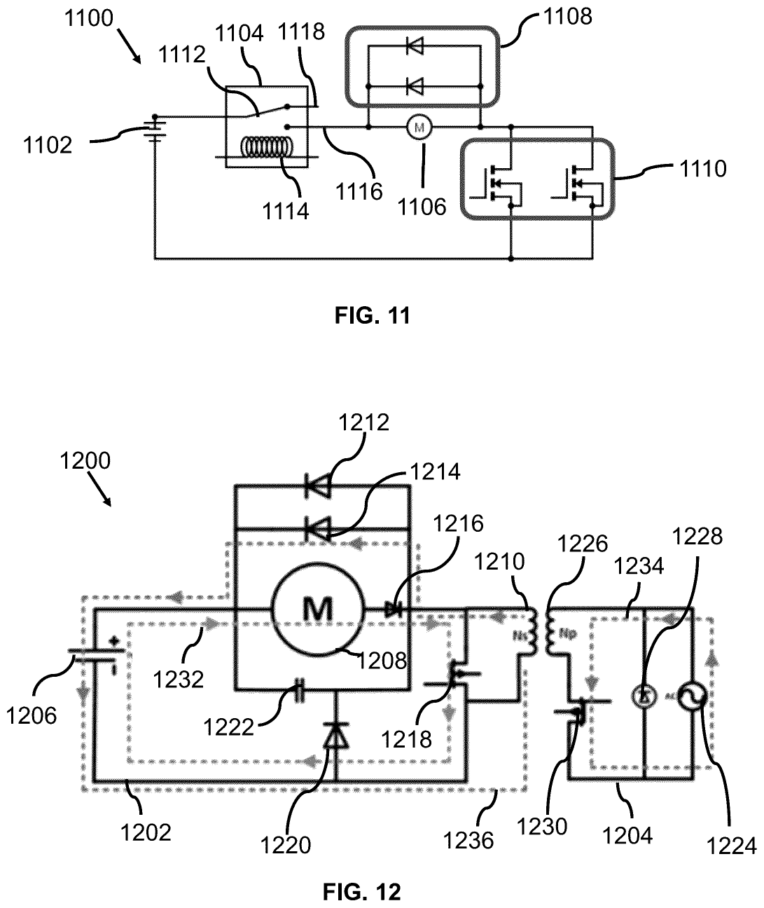

For comparison purposes, a motor control circuit and a motor control and onboard charging circuit in accordance with aspects of the present disclosure will now be described with reference to FIGS. 11-12.

FIG. 11 illustrates a motor control circuit 1100 for an EV.

As shown in the figure, motor control circuit includes a battery 1102, a switch 1104, a motor 1106, a diode bank 1108, and a switch bank 1110. Switch 1104 includes a relay 1112, a solenoid 1114, an output line 1116, and an input line 1118.

Solenoid 1114 is configured to switch relay 1112 between connections with output line 1116 and input line 1118. In a charging mode, switch relay 1112 is connected with input line 1118, and an input voltage is provided to battery 1102 to charge battery 1102. In a driving mode, switch relay 1112 is connected with output line 1116, wherein battery 1102 discharges a voltage to drive motor 1106.

Diode bank 1108 includes a plurality of diodes connected in parallel to prevent the reverse current flow, i.e. from current motor 1106 to battery 1102, as this can cause damage.

Switch bank 1110 controls/regulates the output voltage. Switch bank 1110 my include switches that operate at very high frequencies, a non-limiting example of which includes 65 KHz, to change the input battery voltage level to the one desired by the user (via throttle—not shown), which in-turn changes the speed of motor 1106. Switch bank 1110 includes a plurality of switches connected in parallel so that the load current divides between them and each switch is exposed to a lesser amount of current, increasing the reliability and decreasing power losses.

FIG. 12 illustrates a motor control and onboard charging circuit 1200 of an integrated power module for use with an EV in accordance with aspects of the present disclosure.

As shown in the figure, motor control and onboard charging circuit 1200 includes a motor control circuit portion 1202 and an onboard charging circuit portion 1204. Motor control circuit portion 1202 includes a battery 1206, a motor 1208, a secondary winding 1210, a diode 1212, a diode 1214, a diode 1216, a switch 1218, a diode 1220, and a capacitor 1222. Onboard charging circuit portion 1204 includes an alternating current source 1224, a primary winding 1226, a diode 1228, and a switch 1230.

In a driving mode, battery 1206 is configured to discharge and provide DC electricity to motor 1208 to drive motor 1208 to propel the EV. More specifically, the battery is configured to discharge and provide DC electricity of motor drive PCB 504, which converts the DC electricity to AC electricity, which is then provided to motor 1208 to propel the EV. Switch 1218 enables current to flow from battery 1206 through motor 1208, through diode 1216 and back to battery 1206 as shown by dotted arrows 1232. Capacitor 1222 operates as a high pass filter, preventing returning current from passing through diode 1220 and back to motor 1208.

In a charging mode, onboard charging circuit portion 1204 receives AC electricity from an external source, for example as discussed above with reference to plug 508 in FIG. 5. This external source is represented by alternating current source 1224. In accordance with aspects of the present disclosure, onboard charging circuit portion 1204 operates in a DCM. Accordingly, diode 1228 operates at zero current before becoming reverse biased. Switch 1230 opens, enabling a current flow indicated by dashed arrows 1234, wherein the AC current provided by alternating current source 1224 magnetizes a core (not shown) of primary winding 1226.

The flux in the magnetized core creates current, and a corresponding voltage, in secondary winding 1210. A portion of the generated voltage in secondary winding 1210 actuates switch 1218 to cause motor control circuit portion 1202 to operate in the charging mode. The remainder of voltage generated in secondary winding 1210 passes through diodes 1212 and 1214 to charge battery 1206. The current flow in the charging mode in motor control circuit portion 1202 is illustrated by dotted arrows 1236. In this mode, diode 1216 prevents current from secondary winding 1210 from passing through motor 1208. Similarly, capacitor 1222 again acts as a high pass filter, preventing returning current originating from battery 1206 to bypass secondary winding 1210 via diode 1220 and return to battery 1206.

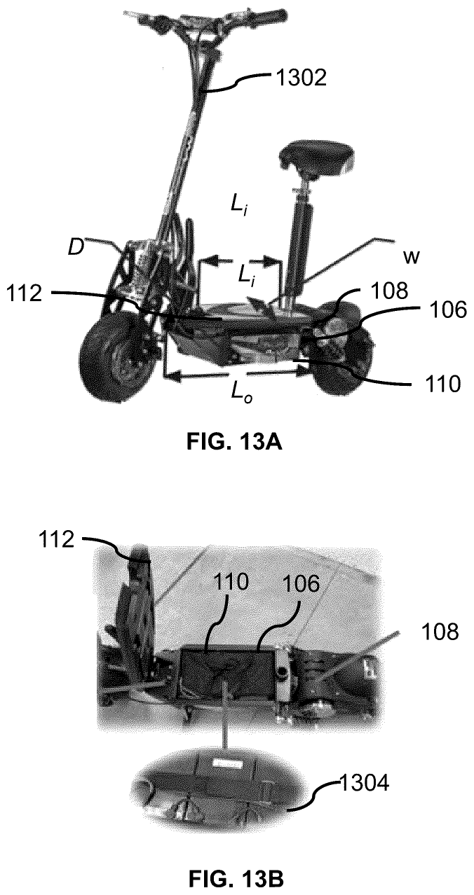

FIG. 13A illustrates an EV system 1300 that includes an EV 1302 in accordance with aspects of the present disclosure. FIG. 13B illustrates a blown-up view of portions of the EV of FIG. 13A.

EV system 1300 differs from EV system 100 of FIGS. 1A-B, in that EV system 1300 does not include an off-board charger. Further, by comparing FIG. 1B with FIG. 13B, it is shown that EV system 1300 does not include a separate motor dive 116. On the contrary, in accordance with aspects of the present disclosure, body compartment 110 of EV system 1300 includes a combination of batteries and IPM 1304. In other words, the combination of batteries and IPM 1304 includes a motor drive PCB having a BDSD embedded therein and an onboard charger PCB having a planar transformer embedded therein.

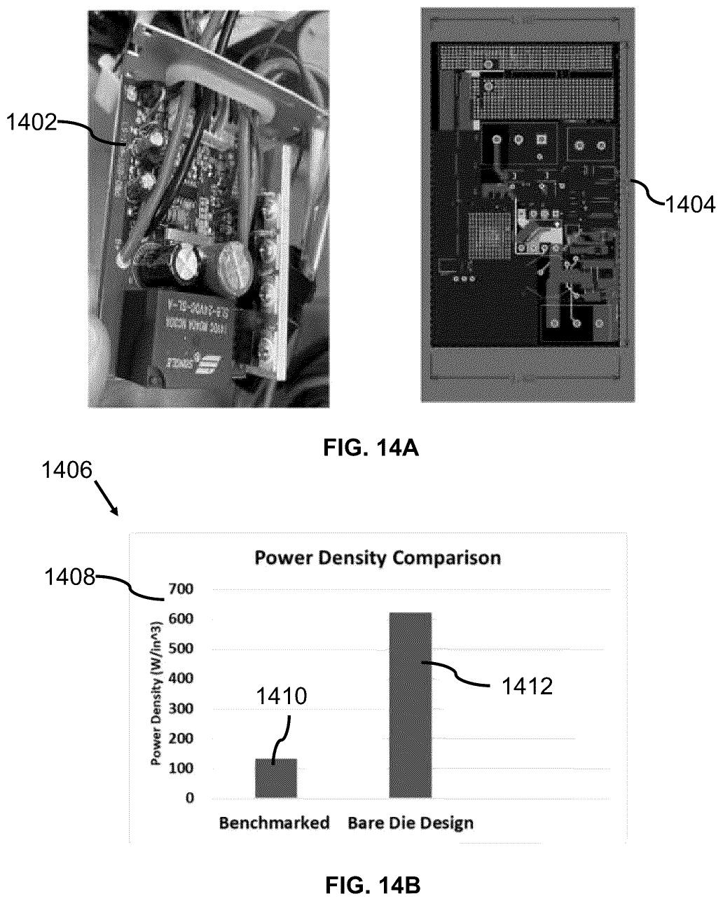

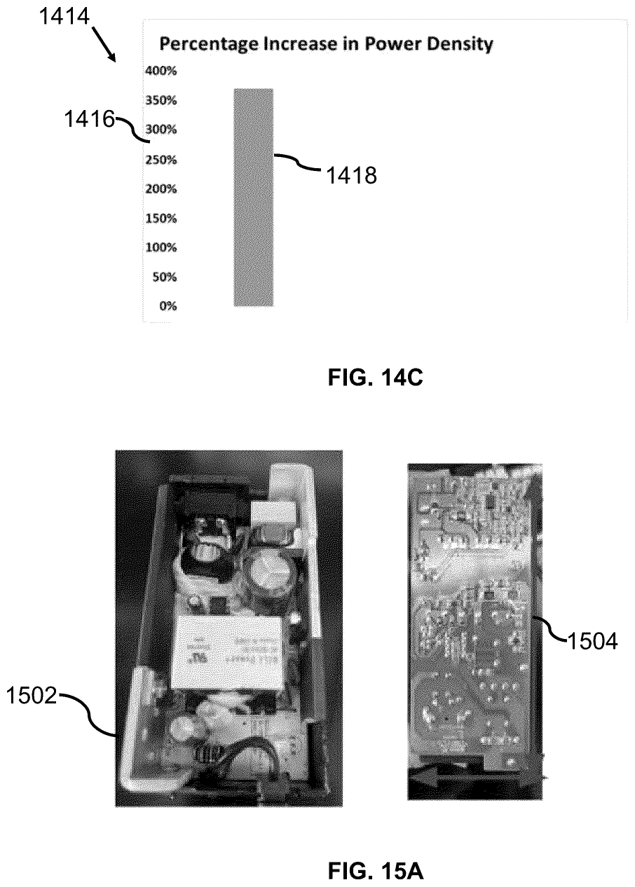

FIG. 14A illustrates a comparative view of a motor control circuit board 1402, and a motor control PCB 1404 having an embedded BDSD therein in accordance with aspects of the present disclosure.

In these examples, motor control circuit board 1402 has: a length of 7.5 cm (2.952 in); a width of 5.5 cm (2.165 in); and a height of 3 cm (1.181 in), thus having a total volume of 0.1917 m³(7.5478 in³). The power density, meaning the amount of power produced by motor control circuit board 1402 divided by the volume of space taken up by motor control circuit board 1402, is 132.48 W/in³.

By comparison, motor control PCB 1404 having an embedded BDSD therein has: a length of 6.95 cm (2.74 in); a width of 4.267 cm (1.68 in); a PCB thickness of 1.877 mm (0.0739 in); and a height of 8.874 mm (0.349 in). The power density is 621.805 W/in³

FIG. 14B illustrates a bar graph 1406 of power density of motor control circuit board 1402 and motor drive PCB 1404.

As shown in the figure, bar graph 1406 includes a y-axis 1408, a bar 1410 and a bar 1412. Y-axis 1408 corresponds to power density in W/in³. Bar 1410 corresponds to the power density of motor control circuit 1402 of FIG. 14A, whereas bar 1414 corresponds to the power density of motor control PCB 1404 having an embedded BDSD therein of FIG. 14A. In other words, y-axis 1408 measures the amount of provided power divided by the volume circuit board.

FIG. 14C illustrates a bar graph 1414 of a percentage increase in power density of motor control circuit board 1402 and motor drive PCB 1404. As shown by the figure, by using a motor drive PCB having an embedded BDSD in accordance with aspects of the present disclosure, an increase of 370% power density is observed.

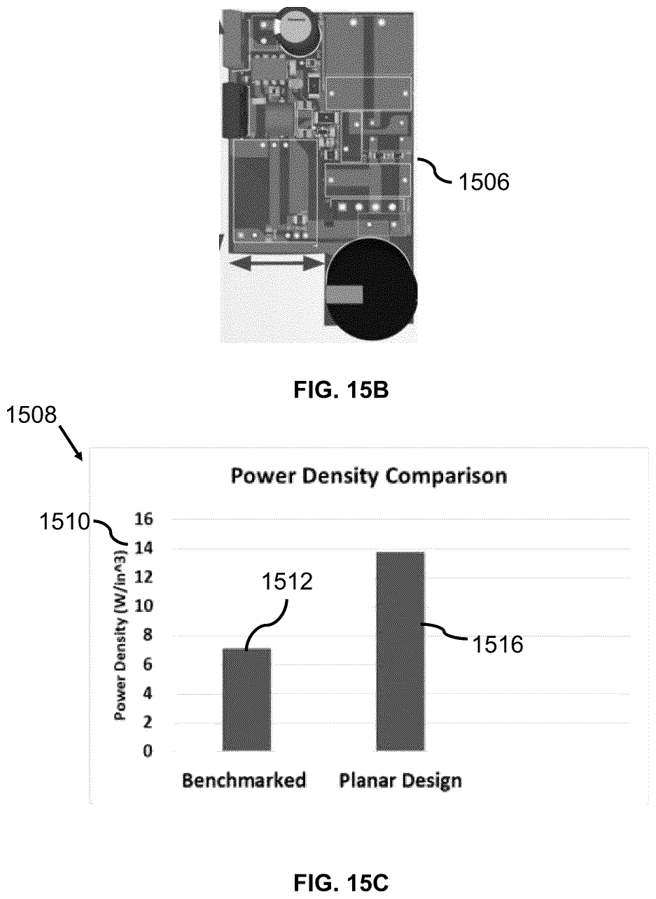

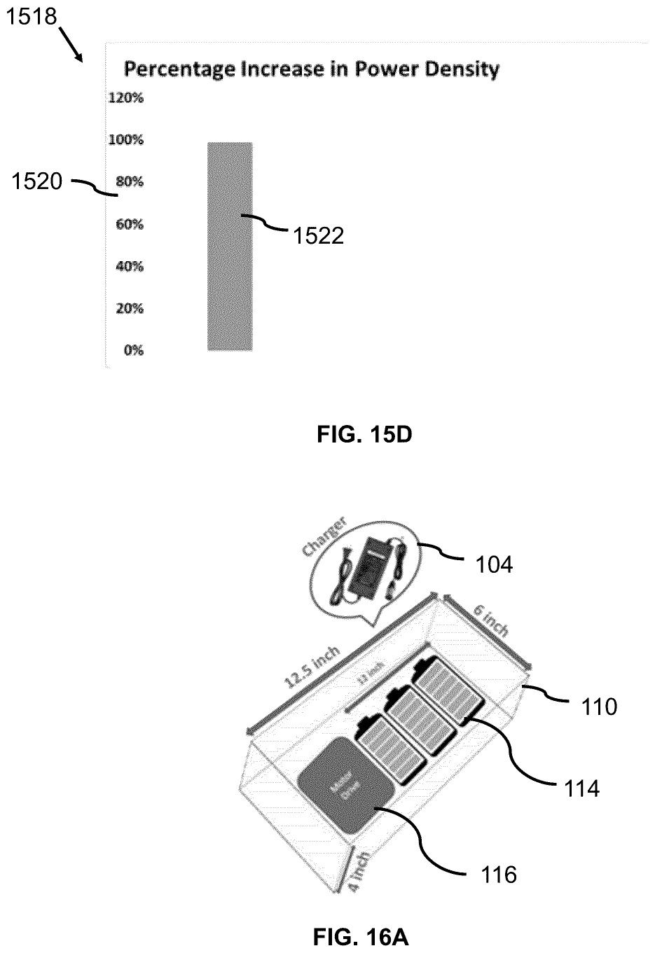

FIG. 15A illustrates an off-board charger 1502 with the top removed and the back 1504 of the PCB of off-board charger 1502. The off-board charger 1502 has a power density of 7.0939 W/in³.

FIG. 15B illustrates a planar view of an example onboard charger PCB 1506 having an embedded planar transformer in accordance with aspects of the present disclosure.

FIG. 15C illustrates a bar graph 1508 of power density of off-board charger 1502 and onboard charger PCB 1506 having an embedded planar transformer in accordance with aspects of the present disclosure.

As shown in the figure, bar graph 1508 includes a y-axis 1510, a bar 1512 and a bar 1516. Y-axis 1510 corresponds to power density in W/in3. Bar 1512 corresponds to the power density of off-board charger 1502 of FIG. 15A, whereas bar 1516 corresponds to the power density of onboard charger PCB 1506 having an embedded planar transformer of FIG. 15B. In other words, y-axis 1510 measures the amount of provided power divided by the volume circuit board.

FIG. 15D illustrates a bar graph 1518 of the percentage increase in power density of an onboard charger PCB 1506 having embedded planar transformer in accordance with aspects of the present disclosure over that of off-board charger 1502.

As shown by the figure, bar graph 1518 includes a y-axis 1520 and a bar 1522. Y-axis 1510 corresponds to a percentage increase in power density. Bar 1522 corresponds to the percentage increase of power density of onboard charger PCB 1506 having an embedded planar transformer of FIG. 15B over that of off-board charger 1502 of FIG. 15A. By using an onboard charger PCB 1506 having embedded planar transformer in accordance with aspects of the present disclosure, an increase of 100% power density is observed.

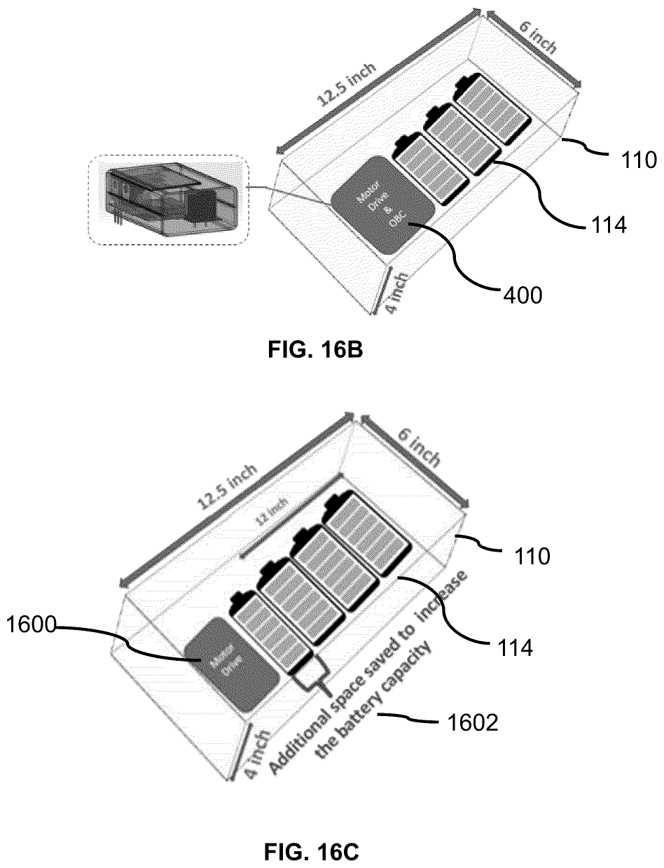

FIG. 16A illustrates the size of the components of body compartment 110.

As shown in the figure, body compartment 110 includes batteries 114 and motor drive 116. Body compartment 110 has a length of 12.5 inches, a width of 6 inches, and a depth of 4 inches, resulting in a total volume of 300 in³. In this example, batteries 114 are illustrated as a plurality of batteries encompassing 12 inches of the 12.5 inches in length of body compartment 110.

FIG. 16B illustrates the size of an example IPM 400 in accordance with aspects of the present disclosure. As shown in the figure, body compartment 110 includes batteries 114 and IPM 400. Therefore, as compared to body compartment 110 as shown in FIG. 16A, in accordance with aspects of the present disclosure, an onboard charger is included without decreasing battery space.

In some embodiments, space within body compartment 110 may be further increased for batteries. This will be described in greater detail with reference to FIG. 16C.

FIG. 16C illustrates the size of another example motor drive module in accordance with aspects of the present disclosure. As shown in the figure, body compartment 110 includes batteries 114, a motor drive module 1600, and an additional battery 1602. In this embodiment, motor drive module 1600 includes motor drive PCB 504 having BDSD 522 embedded therein. Be eliminating onboard charger PCB 506, space is provided for additional battery 1602.

The embodiment of FIG. 16C will share the charging inflexibility of some other EVs, as the user will have to carry a separate off-board charger or return to the starting point for charging purposes. However, the embodiment of FIG. 16C will provide further driving range as a result of additional battery 1602.

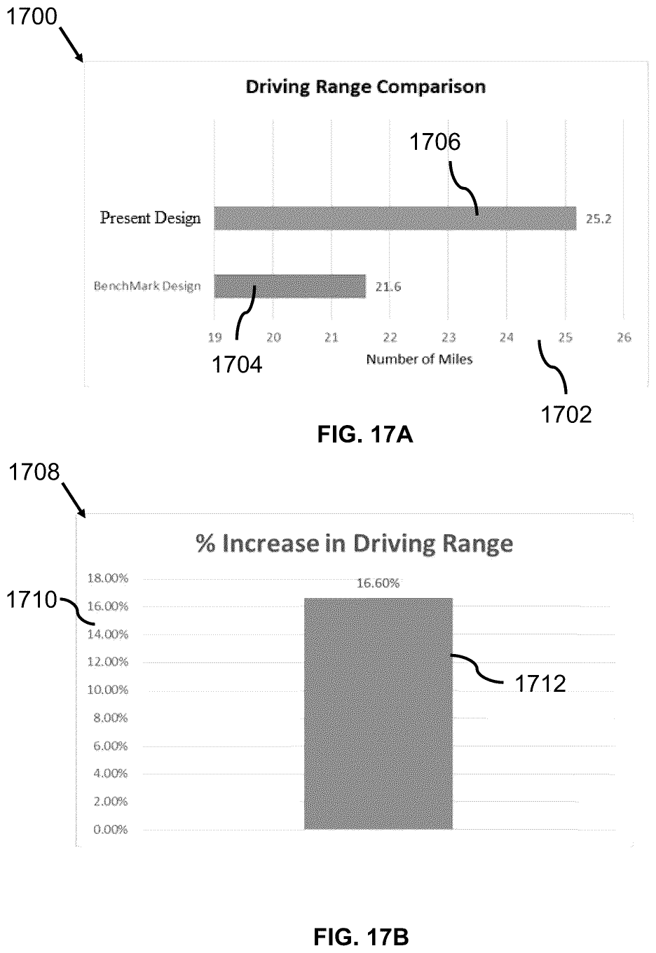

FIG. 17A illustrates a bar graph 1700 of driving range of an EV and an EV using an IPM in accordance with aspects of the present disclosure.

As shown in the figure, bar graph 1700 includes an X-axis 1702, a bar 1704 and a bar 1706. X-axis 1702 has units of number of miles, indicating how far an EV can travel on a single full charge. Bar 1704 corresponds to an EV, whereas bar 1706 corresponds to an EV using an IPM in accordance with aspects of the present disclosure. As seen in bar graph 1700, an EV can travel 21.6 miles on a single full charge, whereas an EV using an IPM in accordance with aspects of the present disclosure can travel 25.2 miles on a single full charge.

FIG. 17B illustrates a bar graph of the percentage change in driving range of an EV as compared to an EV using an example IPM in accordance with aspects of the present disclosure.

As shown by the figure, bar graph 1708 includes a y-axis 1710 and a bar 1712. Y-axis 1710 corresponds to a percentage increase in driving range. Bar 1712 corresponds to the percentage change in driving range of an EV as compared to an EV using an example IPM in accordance with aspects of the present disclosure. By using an IPM in accordance with aspects of the present disclosure, an increase of 16.6% in driving range is observed.

The lack of onboard charging capability is one of the major challenges for the widespread adaptation of small mobility vehicles such as electric scooters, which arises due to the limited space for power electronics units on the chassis of the e-scooters. Magnetics design is the bottleneck for increasing the power density, and it is also the reason that the e-scooters come with a separate off-board charger as an off-the-shelf planar flyback transformer with the required center airgap and power rating is readily not available in the market.

An IPM in accordance with aspects of the present disclosure solves this problem by designing a very low footprint multi-winding flyback planar transformer, operating in discontinuous conduction mode with an interleaved arrangement of windings, resulting in a height of only 12 mm and improved current density distribution. An IPM in accordance with aspects of the present disclosure includes both the onboard charger and motor drive. A benchmark comparison in terms of power density discussed above highlights the achieved benefits. An IPM in accordance with aspects of the present disclosure, enables a user to charge anywhere without carrying a separate off-board charger.

The foregoing description of various preferred embodiments have been presented for purposes of illustration and description. It is not intended to be exhaustive or to limit the present disclosure to the precise forms disclosed, and obviously many modifications and variations are possible in light of the above teaching. The example embodiments, as described above, were chosen and described in order to best explain the principles of the present disclosure and its practical application to thereby enable others skilled in the art to best utilize the present disclosure in various embodiments and with various modifications as are suited to the particular use contemplated. It is intended that the scope of the present disclosure be defined by the claims appended hereto.

What is claimed is:

1. An integrated power module for use with an electric vehicle, said power module comprising:
a motor drive printed circuit board having a bare-die semiconductor device embedded therein; and
an onboard charger printed circuit board having a planar transformer embedded therein and an electrical connector, said onboard charger printed circuit board being configured to operate in a charging mode to supply a first amount of electricity to a battery of the electric vehicle,
wherein said electrical connector is configured to supply the first amount of electricity from an external electricity source and to said planar transformer.

2. The integrated power module of claim 1, further comprising a housing configured to house said motor drive printed circuit board and said onboard charger printed circuit board.

3. The integrated power module of claim 2, wherein said housing is further configured to house the battery of the electric vehicle.

4. The integrated power module of claim 1, wherein said motor drive printed circuit board comprises:
a first printed circuit board layer;
a second printed circuit board layer;
a third printed circuit board layer; and
a fourth printed circuit board layer,
wherein said second printed circuit board layer is disposed between said first printed circuit board layer and said third printed circuit board layer,
wherein said third printed circuit board layer is additionally disposed between said second printed circuit board layer and said fourth printed circuit board layer, and
wherein said bare-die semiconductor device is embedded between said second printed circuit board layer and said third printed circuit board layer.

5. The integrated power module of claim 1, wherein said planar transformer comprises a flyback transformer.

6. The integrated power module of claim 5, wherein said flyback transformer comprises:
a primary winding configured to generate primary winding magnetic flux from the first amount of electricity from the external electricity source;
a primary-side auxiliary winding configured to couple with said primary winding to generate primary auxiliary electricity from the primary winding magnetic flux for use by said onboard charger printed circuit board;
a secondary-side auxiliary winding configured to couple with said primary winding to generate secondary auxiliary electricity from the primary winding magnetic flux for use by said motor drive printed circuit board; and
a secondary-side winding configured to couple with said primary winding to generate a second amount of electricity to be provided to the battery from the primary winding magnetic flux.

7. The integrated power module of claim 1, wherein said motor drive printed circuit board additionally comprises:
a copper via connected to said bare-die semiconductor device; and
a thermal via to provide a path for heat to flow from said bare-die semiconductor device.

8. An electric vehicle comprising:
an electric motor;
a battery configured to store electricity and to supply the stored electricity to said electric motor; and
an integrated power module configured to provide a first amount of electricity to said battery,
wherein said integrated power module comprises:
a motor drive printed circuit board having a bare-die semiconductor device embedded therein; and
an onboard charger printed circuit board having a planar transformer embedded therein and an electrical connector, said onboard charger printed circuit board being configured to operate in a charging mode to supply the first amount of electricity to said battery,
wherein said electrical connector is configured to supply the first amount of electricity from an external electricity source and to said planar transformer.

9. The electric vehicle of claim 8, wherein said integrated power module further comprises a housing configured to house said motor drive printed circuit board and said onboard charger printed circuit board.

10. The electric vehicle of claim 9, wherein said housing is further configured to house the battery of the electric vehicle.

11. The electric vehicle of claim 8, wherein said motor drive printed circuit board comprises:
a first printed circuit board layer;
a second printed circuit board layer;
a third printed circuit board layer; and
a fourth printed circuit board layer,
wherein said second printed circuit board layer is disposed between said first printed circuit board layer and said third printed circuit board layer,
wherein said third printed circuit board layer is additionally disposed between said second printed circuit board layer and said fourth printed circuit board layer, and
wherein said bare-die semiconductor device is embedded between said second printed circuit board layer and said third printed circuit board layer.

12. The electric vehicle of claim 8, wherein said planar transformer comprises a flyback transformer.

13. The electric vehicle of claim 12, wherein said flyback transformer comprises:
a primary winding configured to generate primary winding magnetic flux from a third amount of electricity from the external electricity source;
a primary-side auxiliary winding configured to couple with said primary winding to generate primary auxiliary electricity from the primary winding magnetic flux for use by said onboard charger printed circuit board;
a secondary-side auxiliary winding configured to couple with said primary winding to generate secondary auxiliary electricity from the primary winding magnetic flux for use by said motor drive printed circuit board; and
a secondary-side winding configured to couple with said primary winding to generate the first amount of electricity to be provided to the electric vehicle from the primary winding magnetic flux.

14. The electric vehicle of claim 8, wherein said motor drive printed circuit board additionally comprises:
a copper via connected to said bare-die semiconductor device; and
a thermal via to provide a path for heat to flow from said bare-die semiconductor device.

15. A method of operating an electric vehicle having an electric motor, a battery and an integrated power module, said method comprising:
providing, in an electricity-supplying state, a first amount of electricity to the electric motor from the battery; and
charging, in a charging mode and via the integrated power module, the battery from an external electricity source,
wherein the integrated power module comprises:
a motor drive printed circuit board having a bare-die semiconductor device embedded therein; and
an onboard charger printed circuit board having a planar transformer embedded therein and an electrical connector, the onboard charger printed circuit board being configured to operate in the charging mode to supply a first amount of electricity to the battery,
wherein said electrical connector is configured to supply the first amount of electricity from the external electricity source and to the planar transformer.

16. The method of claim 15, wherein said charging, in a charging state and via the integrated power module, the battery from the external electricity source comprises charging via the integrated power module further comprises a housing configured to house the motor drive printed circuit board and the onboard charger printed circuit board.

17. The method of claim 16, wherein said charging, in a charging state and via the integrated power module, the battery from the external electricity source comprises charging via the integrated power module wherein the housing is further configured to house the battery.

18. The method of claim 15, wherein said charging, in a charging state and via the integrated power module, the battery from the external electricity source comprises charging via the integrated power module wherein the motor drive printed circuit board comprises:
a first printed circuit board layer;
a second printed circuit board layer;
a third printed circuit board layer; and
a fourth printed circuit board layer,
wherein the second printed circuit board layer is disposed between the first printed circuit board layer and the third printed circuit board layer,
wherein the third printed circuit board layer is additionally disposed between the second printed circuit board layer and the fourth printed circuit board layer, and
wherein the bare-die semiconductor device is embedded between the second printed circuit board layer and the third printed circuit board layer.

19. The method of claim 15, wherein said charging, in a charging state and via the integrated power module, the battery from the external electricity source comprises charging via the integrated power module wherein the planar transformer comprises a flyback transformer.

20. The method of claim 19, wherein said charging, in a charging state and via the integrated power module, the battery from the external electricity source comprises charging via the integrated power module wherein the flyback transformer comprises:
a primary winding configured to generate primary winding magnetic flux from the first amount of electricity from the external electricity source;
a primary-side auxiliary winding configured to couple with the primary winding to generate primary auxiliary electricity from the primary winding magnetic flux for use by the onboard charger printed circuit board;
a secondary-side auxiliary winding configured to couple with the primary winding to generate secondary auxiliary electricity from the primary winding magnetic flux for use by the motor drive printed circuit board; and
a secondary-side winding configured to couple with the primary winding to generate a second amount of electricity to be provided to the battery from the primary winding magnetic flux.
